(19) United States
(12) Patent Application Publication
(10) Pub. No.: US 2007/0267672 A1
(43) Pub. Date: Nov. 22, 2007

(54) SEMICONDUCTOR DEVICE AND METHOD FOR MANUFACTURING SAME

(75) Inventors: Yoshitaka HOKOMOTO, Kanagawa-ken (JP); Akio Takano, Kanagawa-ken (JP); Shunsuke Katoh, Hyogo-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/744,344

(22) Filed: May 4, 2007

(30) Foreign Application Priority Data
May 18, 2006 (JP) 2006-139228

(51) Int. Cl. H01L 29/94; H01L 27/108; H01L 29/76; H01L 31/119; H01L 21/8242

(52) U.S. Cl. 257/301; 438/243

(57) ABSTRACT

A semiconductor device includes: a first semiconductor layer of a first conductivity type; a second semiconductor layer of a second conductivity type provided on the first semiconductor layer; a plurality of first trenches passing through the second semiconductor layer and reaching the first semiconductor layer; a gate insulating film provided on an inner wall of the first trench; and a gate electrode filling in the first trench via the gate insulating film. A PN junction interface is provided between the first semiconductor layer and the second semiconductor layer. A distance from an upper face of the second semiconductor layer to the PN junction interface is minimized nearly at a center between the first trenches.

### CROSS-REFERENCE TO RELATED APPLICATIONS

This application is based upon and claims the benefit of priority from the prior Japanese Patent Application No. 2006-139228, filed on May 18, 2006; the entire contents of which are incorporated herein by reference.

### BACKGROUND OF THE INVENTION

1. Field of the Invention

This invention relates to a semiconductor device and a method for manufacturing the same, and more particularly to a semiconductor device having a trench gate structure and a method for manufacturing the same.

2. Background Art

MOS semiconductor devices such as power MOSFET and IGBT (Insulated Gate Bipolar Transistor) are used as power controlling semiconductor devices. The recent demand for energy saving requires highly efficient semiconductor devices. For increasing the efficiency of power controlling semiconductor devices, the reduction of conduction loss (that is, the reduction of ON resistance) of the device is required. To this end, the cell is downscaled to reduce ON resistance. In particular, the trench gate structure is used in the device structure to increase the channel density, thereby realizing significant downscaling.

In this context, there is a strong demand for a trench gate semiconductor device and a method for manufacturing the same where the number of photolithography steps can be decreased toward the reduction of manufacturing cost and power loss can be also reduced. A Japanese patent document JP 11-026758A discloses an example of reducing the number of photolithography steps. In this patent document, a mask for forming trenches is set back by isotropic etching, and then diverted to a mask for ion implantation to form a source region and a well region in a self-aligned manner.

### SUMMARY OF THE INVENTION

According to an aspect of the invention, there is provided a semiconductor device including: a first semiconductor layer of a first conductivity type; a second semiconductor layer of a second conductivity type provided on the first semiconductor layer; a plurality of first trenches passing through the second semiconductor layer and reaching the first semiconductor layer; a gate insulating film provided on an inner wall of the first trench; and a gate electrode filling in the first trench via the gate insulating film, a PN junction interface being provided between the first semiconductor layer and the second semiconductor layer, and a distance from an upper face of the second semiconductor layer to the PN junction interface being minimized nearly at a center between the first trenches.

According to another aspect of the invention, there is provided a semiconductor device including: a first semiconductor layer of a first conductivity type; a second semiconductor layer of a second conductivity type provided on the first semiconductor layer; a plurality of first trenches passing through the second semiconductor layer and reaching the first semiconductor layer; a gate insulating film provided on an inner wall of the first trench; a gate electrode filling in the first trench via the gate insulating film; a plurality of first diffusion regions of the first conductivity type selectively provided in the upper surface of the second semiconductor layer; and a contact region of the second conductivity type provided between the first diffusion regions in the second semiconductor layer, a PN junction interface being provided between the first semiconductor layer and the second semiconductor layer, and the PN junction interface having a protruding feature at a position corresponding to the contact region.

According to another aspect of the invention, there is provided a method for manufacturing a semiconductor device including: forming a first insulating film on an upper face of a first semiconductor crystal layer of a first conductivity type; forming a plurality of first openings in the first insulating film and then partially removing the first semiconductor crystal layer exposed in the first openings to form a plurality of first trenches; setting back the first insulating film having the first openings to form a second insulating film and to expose an upper corner of the first trench; forming a gate insulating film on an inner wall of the first trench; filling in the first trench with a gate electrode material via the gate insulating film; introducing a first dopant of a second conductivity type and a second dopant of the first conductivity type into the corner and the gate electrode material, respectively, by ion implantation from above the first semiconductor crystal layer using the second insulating film as a mask; and thermally diffusing the first dopant and the second dopant introduced into the corner and the gate electrode material to convert the gate electrode material into a conductor of the first conductivity type, to form a second semiconductor layer of the second conductivity type in the first semiconductor crystal layer, and to form a diffusion region of the first conductivity type in the corner.

### BRIEF DESCRIPTION OF THE DRAWINGS

FIG. 1 is a schematic view illustrating the cross-sectional structure of a trench gate semiconductor device according to a first embodiment of the invention, corresponding to a cross-sectional view taken along the A-A line of FIG. 2.

FIG. 2 is a perspective plan view illustrating the electrode structure of the trench gate semiconductor device of FIG. 1.

FIG. 3 is a cross-sectional view showing a process for manufacturing the trench gate semiconductor device of FIG. 1.

FIG. 4 is a cross-sectional view showing a process for manufacturing the trench gate semiconductor device of FIG. 1.

FIG. 5 is a cross-sectional view showing a process for manufacturing the trench gate semiconductor device of FIG. 1.

FIG. 6 is a cross-sectional view showing a process for manufacturing the trench gate semiconductor device of FIG. 1.

FIG. 7 is a cross-sectional view showing a process for manufacturing the trench gate semiconductor device of FIG. 1.

FIG. 8 is a cross-sectional view showing a process for manufacturing the trench gate semiconductor device of FIG. 1.

FIG. 9 is a cross-sectional view showing a process for manufacturing the trench gate semiconductor device of FIG. 1.

FIG. 10 is a schematic view illustrating the cross-sectional structure of a trench gate semiconductor device according to a second embodiment of the invention.

FIG. 11 is a cross-sectional view showing a process for manufacturing the trench gate semiconductor device of FIG. 9.

FIG. 12 is a cross-sectional view showing a process for manufacturing the trench gate semiconductor device of FIG. 9.

FIG. 13 is a cross-sectional view showing a process for manufacturing the trench gate semiconductor device of FIG. 9.

### DETAILED DESCRIPTION OF THE INVENTION

Embodiments of the invention will now be described with reference to the drawings.

### First Embodiment

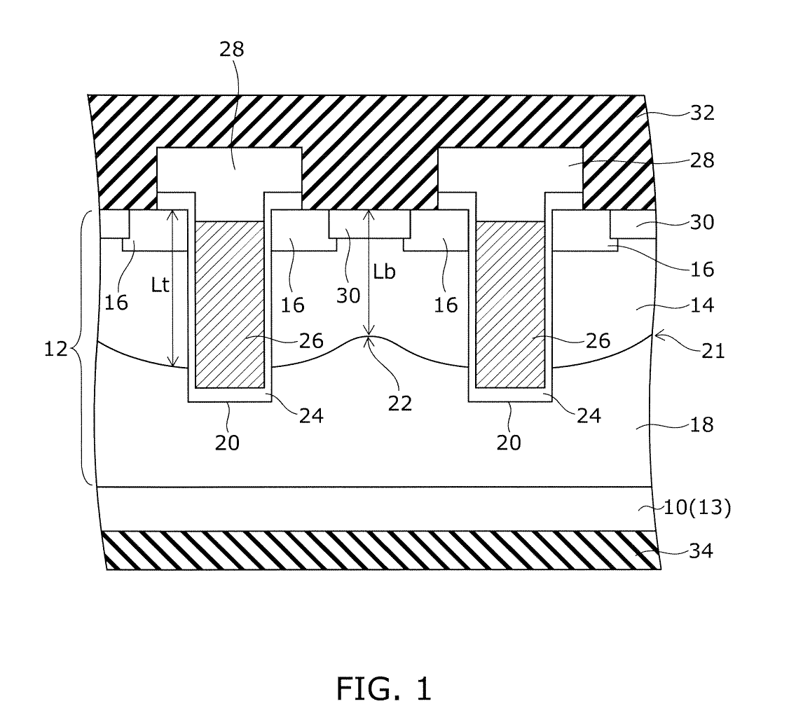

FIG. 1 is a schematic view illustrating the cross-sectional structure of a trench gate semiconductor device according to a first embodiment of the invention. In this description, a trench gate MIS transistor is used as an example of the trench gate semiconductor device.

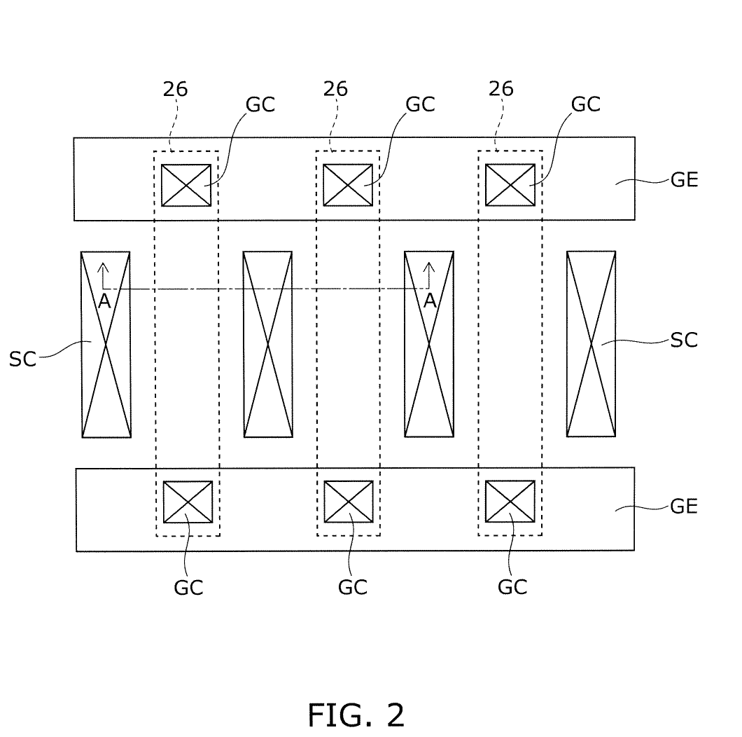

FIG. 2 is a perspective plan view illustrating the electrode structure of the trench gate semiconductor device. Here, FIG. 1 corresponds to a cross-sectional view taken along the A-A line of FIG. 2.

In the following description, the N-type is an example of the first conductivity type, and the P-type is an example of the second conductivity type. In this embodiment, the N-type is represented by “N⁻”, “N”, and “N⁺”, and the P-type is represented by “P⁻”, “P”, and “P⁺”. Relative to “N”, “N⁺” indicates a higher N-type dopant concentration, and “N⁻” indicates a lower N-type dopant concentration. This applies similarly to the P-type.

### Structure of the First Embodiment

As shown in FIG. 1, an N⁻-type epitaxial layer 12 serving as a first semiconductor crystal layer is provided on an N⁺-type semiconductor substrate 10. The N⁺-type semiconductor substrate 10 serves as a drain region 13 of the trench gate MIS transistor. A P-type base layer 14 serving as a second semiconductor layer is provided in the upper portion of the N⁻-type epitaxial layer 12. An N⁺-type source region 16 is selectively provided in the surface portion of the P-type base layer 14. The portion of the N⁻-type epitaxial layer 12 sandwiched between the upper face of the N⁺-type semiconductor substrate 10 and the bottom face of the P-type base layer 14 serves as an N⁻-type drift layer (first semiconductor layer) 18 of the trench gate MIS transistor.

A first trench 20 extends from the upper face side of the N⁻-type epitaxial layer 12, passes through the N⁺-type source region 16 and the P-type base layer 14, and reaches the N-type drift layer 18. A PN junction interface 21 is formed between (at the boundary of) the N-type drift layer 18 and the P-type base layer 14. The PN junction interface 21 has a protruding feature 22 extending toward the upper face of the P-type base layer 14 nearly at the center between adjacent first trenches 20. The protruding feature 22 is designed so that the distance (Lt) from the upper face of the N⁻-type epitaxial layer 12 to the bottom of the P-type base layer 14 adjacent to the sidewall of the first trench is longer than the distance (Lb) from the upper face of the N⁻-type epitaxial layer 12 to the bottom face of the P-type base layer 14 nearly at the center between the first trenches 20. In other words, the protruding feature 22 is designed so that the distance from the upper face of the N⁻-type epitaxial layer 12 to the PN junction interface 21 is minimized nearly at the center between the first trenches 20. The above-mentioned upper face of the N⁻-type epitaxial layer 12 can be also referred to as the upper face of the P-type base layer 14.

Here, inside the P-type base layer 14 adjacent to the sidewall of the first trench 20, it is necessary to prevent the short channel effect and other unwanted phenomena. To this end, the P-type base layer 14 is provided with a channel length required for such prevention. Furthermore, the protruding feature 22 can reduce the extraction resistance from inside the P-type base layer 14 to the source electrode, and the carrier ejection current can be increased. As a result, when the transistor is turned off, carriers (holes) accumulated in the P-type base layer 14 in the conducting state can be rapidly ejected outside the transistor. This will be described in detail in “Major effects of the first embodiment”.

A gate insulating film 24 is provided on the inner wall of the first trench 20. The inside of the first trench 20 is filled with a conductive material (e.g. conductive polysilicon) via the gate insulating film 24. This conductive material is used as a trench gate electrode 26.

An interlayer insulating film 28 is provided so as to cover the top of the trench gate electrode 26 and the exposed portion of the N⁺-type source region 16. A P⁺-type base contact region 30 electrically connected to the P-type base layer 14 is provided in the surface portion between adjacent N⁺-type source regions 16. Here, it can be also restated that the above-mentioned protruding feature 22 is provided at the position in the PN junction interface 21 corresponding to the P⁺-type base contact region 30.

A source electrode 32 is provided so as to cover the interlayer insulating film 28 under the condition that the P⁺-type base contact region 30 and a portion of the N⁺-type source region 16 are exposed. The source electrode 32 is illustratively made of a laminated film composed of TiW or other barrier metal and Al, and is electrically connected to the N⁺-type source region 16 and the P⁺-type base contact region 30. A drain electrode 34 is formed on the backside of the N⁺-type semiconductor substrate 10 serving as the drain region 13.

Next, with reference to FIG. 2, the plan view of the trench gate MIS transistor is described. A plurality of trench gate electrodes 26 extending parallel to each other in FIG. 1 (corresponding to the cross-sectional view taken along the A-A line of FIG. 2) are interconnected by a gate electrode portion GE provided generally orthogonal to these trench gate electrodes 26. Furthermore, the trench gate electrode 26 is connected to a gate interconnect, not shown, through a gate contact GC for the gate electrode portion GE. The source electrode 32 is connected to the N⁺-type source region 16 and the P⁺-type base contact region 30 through a source contact SC provided via an interlayer insulating film, not shown. The gate interconnect is insulated from the source electrode 32 by an interlayer insulating film, not shown.

### Operation of the Semiconductor Device of the First Embodiment

The operation of the trench gate MIS transistor is described with reference to FIG. 1. In this operation, the N⁺-type source region 16 and the P⁺-type base contact region 30 are grounded. A prescribed positive voltage is applied via the drain electrode 34 to the N⁺-type semiconductor substrate 10 serving as a drain region 13. The positive voltage applied to the drain electrode 34 is applied also to a channel stopper electrode, not shown.

To turn on the trench gate MIS transistor, a prescribed positive voltage is applied to the trench gate electrode 26. Then an inversion layer is formed in the P-type base layer 14 in contact with the sidewall of the first trench 20. Electrons from the N⁺-type source region 16 pass through this inversion layer, are injected into the N-type drift layer 18, and reach the N⁺-type semiconductor substrate 10 serving as the drain region 13. Hence a current flows from the N⁺-type semiconductor substrate 10 to the N⁺-type source region 16.

On the other hand, to turn off the trench gate MIS transistor, the voltage applied to the trench gate electrode 26 is controlled so that the potential of the trench gate electrode 26 is not more than the potential of the N⁺-type source region 16. Then the inversion layer vanishes in the P-type base layer 14 in contact with the sidewall of the first trench 20, and the injection of electrons from the N⁺-type source region 16 into the N-type drift layer 18 is stopped. Hence no current flows from the N⁺-type semiconductor substrate 10 to the N⁺-type source region 16. During the turnoff, a depletion layer, which extends from the PN junction formed between the N-type drift layer 18 and the P-type base layer 14, depletes the N-type drift layer 18, retaining the withstand voltage of the trench gate MIS transistor.

### Manufacturing Method of the First Embodiment

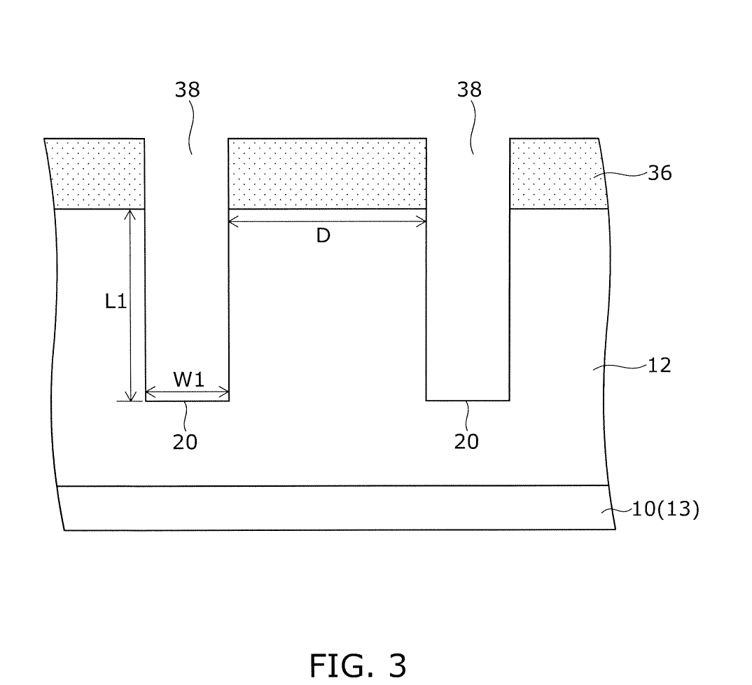

FIGS. 3 to 9 are cross-sectional views showing the process for manufacturing a trench gate MIS transistor according to this embodiment.

As shown in FIG. 3, an N⁻-type epitaxial layer (first semiconductor crystal layer) 12 is formed on an N⁺-type semiconductor substrate 10 by epitaxial growth. Here, the N⁺-type semiconductor substrate 10 (e.g. silicon substrate) is to serve as a drain region 13 of the trench gate MIS transistor. Next, a first insulating film 36 is formed on the N⁻-type epitaxial layer 12 by CVD (Chemical Vapor Deposition) or thermal oxidation. Here, the first insulating film 36 has a thickness of e.g. about 0.5 micrometers.

Next, a plurality of first openings 38 are formed in the first insulating film 36 by selective etching using a resist mask (not shown), for example. Then the N⁻-type epitaxial layer 12 exposed in the first openings 38 is partially removed by dry etching to form a plurality of first trenches 20. The dry etching process can illustratively be RIE (Reactive Ion Etching), CDE (Chemical Dry Etching), or the combination thereof. Here, the length L1 of the sidewall and the width W1 of the bottom of the first trench 20 are e.g. about 1.0 micrometer and about 0.5 micrometers, respectively. The distance D between adjacent first trenches 20 is e.g. 1.5 micrometers.

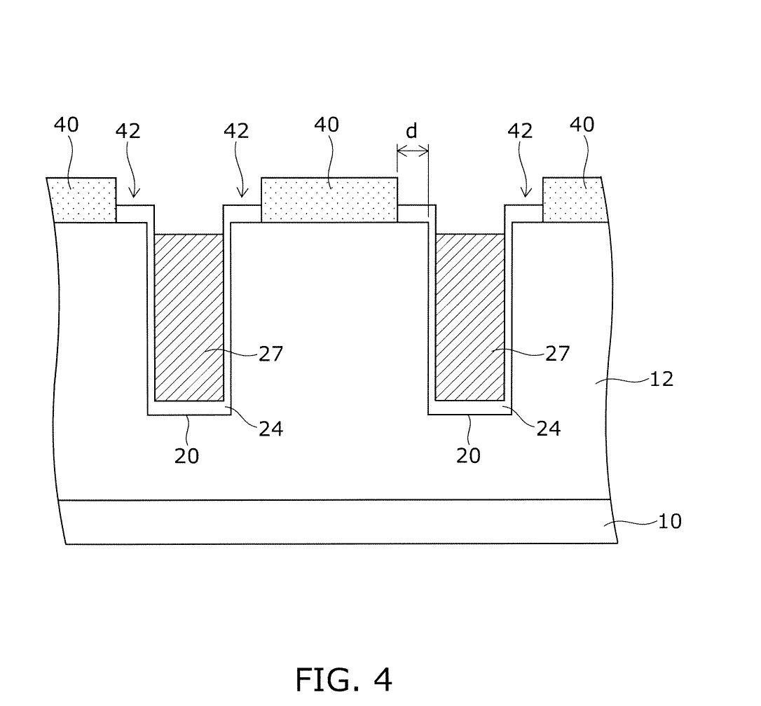

Next, as shown in FIG. 4, the first insulating film 36 is set back by isotropic etching (wet etching or CDE) to form a second insulating film 40. As a result, the upper corner 42 of the first trench 20 is exposed. Here, the amount of setback d of the first insulating film 36 is e.g. about 0.2 micrometers. Then a gate insulating film 24 is formed on the inner wall of the first trench 20 by thermal oxidation or CVD. Next, the inside of the first trench 20 is filled with polysilicon 27, which is to serve as a trench gate electrode 26, via the gate insulating film 24 by CVD.

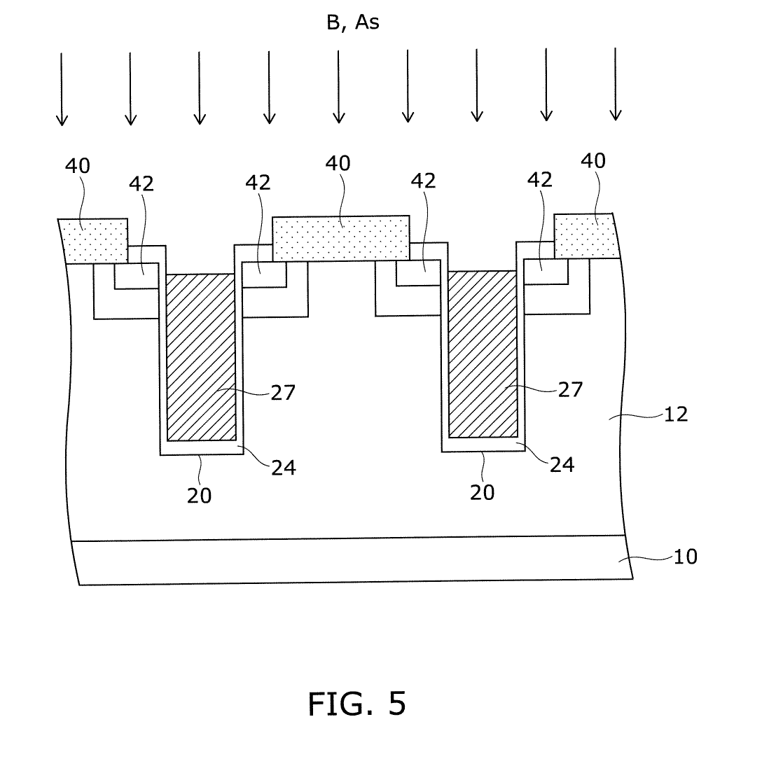

Next, as shown in FIG. 5, the second insulating film 40 is used as a mask to perform ion implantation of e.g. boron and arsenic from above the N⁻-type epitaxial layer 12. As a result, the upper corner 42 of the trench and the polysilicon 27 are doped with boron and arsenic in a self-aligned manner. Here, the boron ion implantation is illustratively performed under the condition of an ion acceleration energy of 60 keV, a dose amount of 3E13 atmos/cm², and an implantation angle (angle relative to the normal to the semiconductor substrate surface) of 7°. On the other hand, the arsenic ion implantation is illustratively performed under the condition of an ion acceleration energy of 65 keV, a dose amount of 3E15 atmos/cm², and an implantation angle (angle relative to the normal to the semiconductor substrate surface) of 7°.

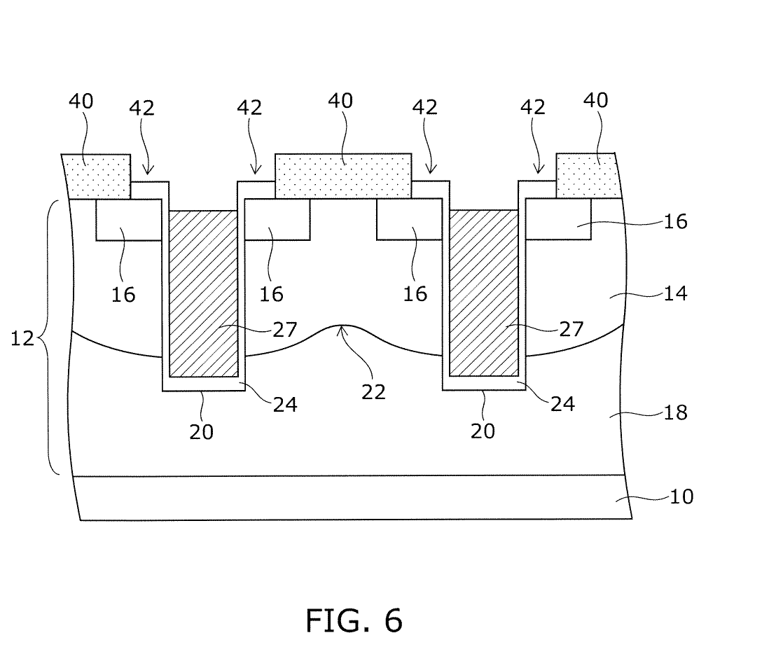

Next, as shown in FIG. 6, the implanted boron and arsenic is thermally diffused (double diffusion of boron and arsenic) to convert polysilicon 27 into an N-type conductor, and a P-type base layer (second semiconductor layer) 14 is formed in the N⁻-type epitaxial layer 12 where the bottom face of the P-type base layer 14 has a protruding feature 22 nearly at the center between adjacent first trenches 20. Similarly, an N⁺-type source region 16 is formed at the upper corner 42 of the first trench 20. Here, boron is diffused more extensively than arsenic because boron has a larger diffusion coefficient by about an order of magnitude at the same diffusion temperature.

As a result, the P-type base layer 14 has a depth of about 1.0 micrometer from the upper face of the N⁻-type epitaxial layer 12 and a dopant concentration of about 1E17 atoms/cm³, and the N⁺-type source region 16 has a depth of about 0.4 micrometers from the upper face of the N⁻-type epitaxial layer 12 and a dopant concentration of about 1E20 atoms/cm³.

Here, the size of the protruding feature 22 can be controlled by appropriately selecting the amount of setback d of the first insulating film 36 and the thermal diffusion temperature of dopant (boron). For example, if the amount of setback d and the thermal diffusion temperature of dopant are increased, the bottom face of the P-type base layer can be made flatter because of the superposition of dopant diffusion from the corners 42.

Here, polysilicon 27 is converted into an N-type conductor because the dose amount of arsenic is higher than the dose amount of boron by about two orders of magnitude.

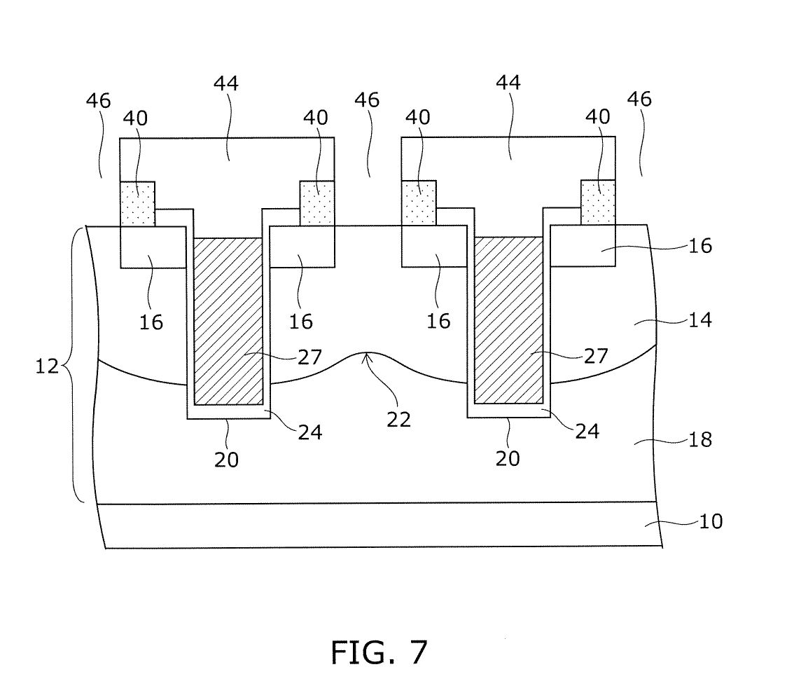

Next, as shown in FIG. 7, an interlayer insulating film 44 is formed by CVD so as to cover the polysilicon 27, the upper corner 42 of the first trench 20, and the second insulating film 40. Next, a second opening 46 is formed by selective etching at a position of the interlayer insulating film 44 corresponding to above the portion between the adjacent first trenches 20.

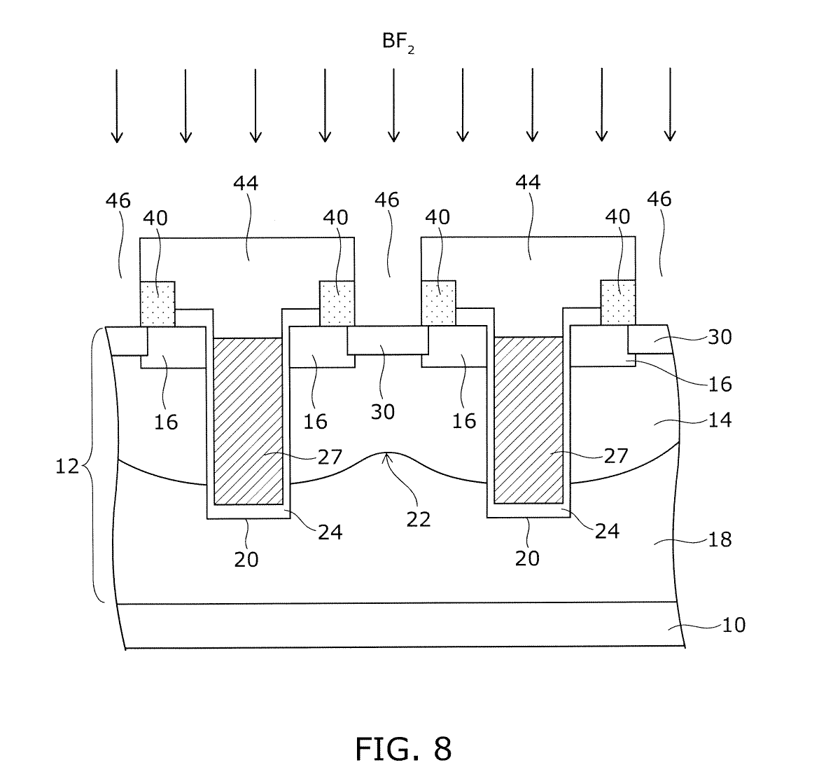

Next, as shown in FIG. 8, ion implantation of BF₂ is performed on the P-type base layer 14 exposed in the second opening 46 from above the interlayer insulating film 44 to form a P⁺-type base contact region 30. Here, the BF₂ ion implantation is illustratively performed under the condition of an ion acceleration energy of 30 keV, a dose amount of 3E15 atmos/cm², and an implantation angle (angle relative to the normal to the semiconductor substrate surface) of 0°. Then the dopants in the P⁺-type base contact region 30 are activated by heat treatment. As a result, the P⁺-type base contact region 30 has a depth of about 0.3 micrometers from the upper face of the N⁻-type epitaxial layer 12 and a dopant concentration of about 1E20 atoms/cm³. When all the activation heat treatments for implanted ions are completed, the distance between the top and the bottom of the protruding feature 22 (=Lt−Lb, see FIG. 1) was about 0.2 to 0.3 micrometers. This derives from the fact that the lateral (the direction parallel to the surface of the semiconductor substrate 10) diffusion distance of dopants is about 80 percent of the dopant diffusion distance in the substrate depth direction.

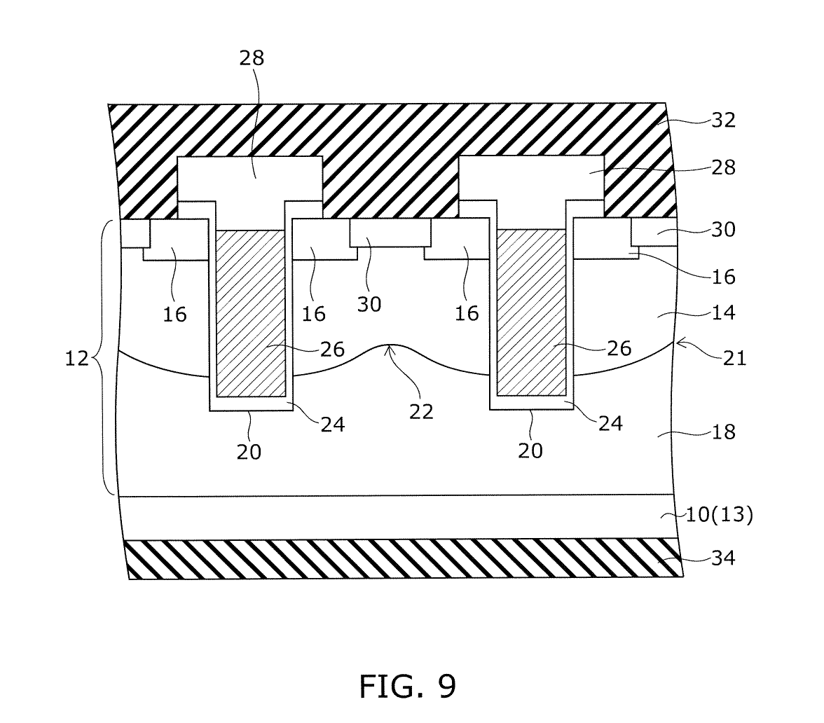

Next, as shown in FIG. 9, the interlayer insulating film 44 is set back by isotropic etching (wet etching or CDE) to partially expose the N⁺-type source region 16. Then a source electrode 32 is provided so as to cover the interlayer insulating film 28 by sputtering under the condition that the P⁺-type base contact region 30 and a portion of the N⁺-type source region 16 are exposed. Here, the source electrode 32 is illustratively made of a laminated film composed of TiW or other barrier metal and Al, and is electrically connected to the N⁺-type source region 16 and the P⁺-type base contact region 30. Then a drain electrode 34 is formed on the backside of the N⁺-type semiconductor substrate 10 by sputtering, for example. Thus a trench gate MIS transistor is completed.

### Major Effects of the First Embodiment

As described above, in this embodiment, a protruding feature 22 is provided on the bottom face of the P-type base layer 14. As shown in FIG. 1, this protruding feature 22 is designed so that the distance (Lt) from the upper face of the N⁻-type epitaxial layer 12 to the bottom of the P-type base layer 14 adjacent to the sidewall of the first trench is longer than the distance (Lb) from the upper face of the N⁻-type epitaxial layer 12 to the bottom face of the P-type base layer 14 nearly at the center between the first trenches 20. In other words, the protruding feature 22 is designed so that the distance from the upper face of the N⁻-type epitaxial layer 12 to the PN junction interface 21 is minimized between the first trenches 20. It can be also restated that the protruding feature 22 is provided at the position in the PN junction interface 21 corresponding to the P⁺-type base contact region 30. The above-mentioned upper face of the N⁻-type epitaxial layer 12 can be also referred to as the upper face of the P-type base layer 14.

Here, inside the P-type base layer 14 adjacent to the sidewall of the first trench 20, it is necessary to prevent the short channel effect and other unwanted phenomena. To this end, the P-type base layer 14 is provided with a channel length required for such prevention. Furthermore, because the protruding feature 22 is provided on the bottom face of the P-type base layer 14, the distance from inside the P-type base layer 14 to the P⁺-type base contact region 30 can be reduced. Thus, during the turnoff of the transistor, the resistance for ejecting carriers from inside the P-type base layer 14 to the source electrode can be reduced, and the carrier ejection current can be increased. As a result, when the trench gate MIS transistor is turned off, the time period for ejecting carriers from the P-type base layer 14 to the source electrode 32 can be reduced. This reduction of turnoff time enables the total amount of power loss (switching loss) occurring during the turnoff to be reduced.

In the manufacturing method of this embodiment, the first insulating film 36 used for forming the first trench 20 is set back by isotropic etching and processed into a second insulating film 40. Then the second insulating film 40 is used as a mask to form the P-type base layer 14, the N⁺-type source region 16, and the trench gate electrode 26 by ion implantation in a self-aligned manner. In conventional methods, the processes for forming the trench, the base layer, and the source region are often performed by photolithography using separate masks. In contrast, in this embodiment, two iterations of photolithography (for the base layer and the source region) can be omitted. As a result, the device manufacturing process can be simplified, and the manufacturing cost can be reduced. Furthermore, the decrease of manufacturing yield due to misalignment of masks can be prevented by reducing the number of masks required for device manufacturing and using the self-alignment technique for forming the P-type base layer, the N⁺-type source region, and the trench gate electrode.

### Second Embodiment

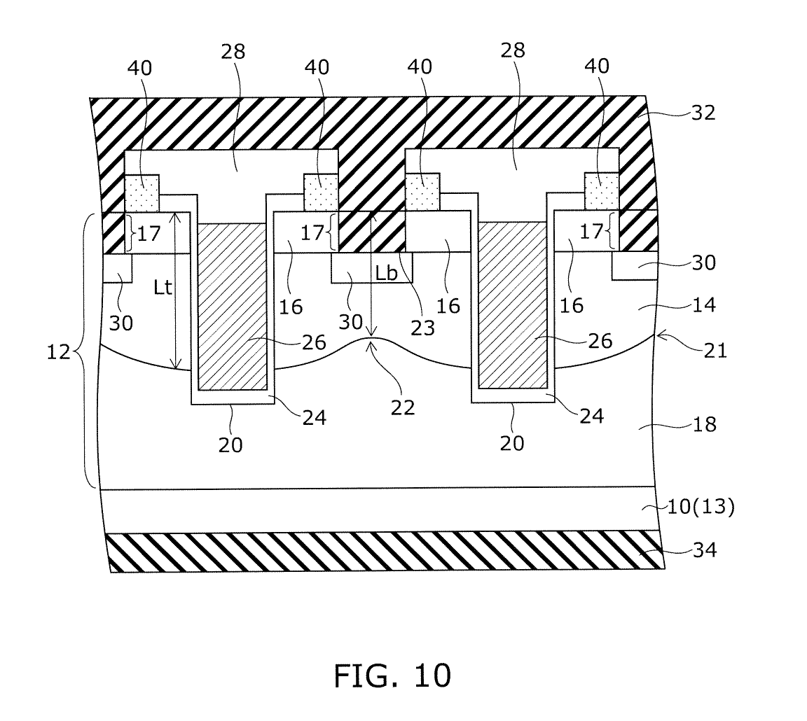

FIG. 10 is a schematic view illustrating the cross-sectional structure of a trench gate semiconductor device according to a second embodiment of the invention. In this description, a trench gate MIS transistor is used as an example of the trench gate semiconductor device.

This embodiment is different from the first embodiment in that the P⁺-type base contact region 30 is provided using the trench contact formation technique. In the figures of this embodiment, the same components as those in the description of the semiconductor device and its manufacturing method of the first embodiment with reference to FIGS. 1 to 9 are marked with the same reference numerals and symbols.

### Structure of the Second Embodiment

The device structure up to the interlayer insulating film 28 provided so as to cover the top of the trench gate electrode 26 and the exposed portion of the N⁺-type source region 16 is the same as that of the first embodiment, and hence the description thereof is omitted.

As shown in FIG. 10, a second trench 23 is provided between adjacent first trenches 20 from above the N⁻-type epitaxial layer (first semiconductor crystal layer) 12 so as to expose the sidewall 17 of the N⁺-type source region 16 and to reach the P-type base layer (second semiconductor layer) 14. A P⁺-type base contact region 30 electrically connected to the P-type base layer 14 is provided at the bottom of the second trench 23.

A source electrode 32 is provided so as to cover the interlayer insulating film 28 under the condition that the P⁺-type base contact region 30 and the sidewall 17 of the N⁺-type source region 16 are exposed. The source electrode 32 is illustratively made of a laminated film composed of TiW or other barrier metal and Al, and is electrically connected to the N⁺-type source region 16 and the P⁺-type base contact region 30. A drain electrode 34 is formed on the backside of the N⁺-type semiconductor substrate 10 serving as the drain region 13.

### Operation of the Semiconductor Device of the Second Embodiment

The operation of the semiconductor device is the same as in the first embodiment, and hence is not described here.

### Manufacturing Method of the Second Embodiment

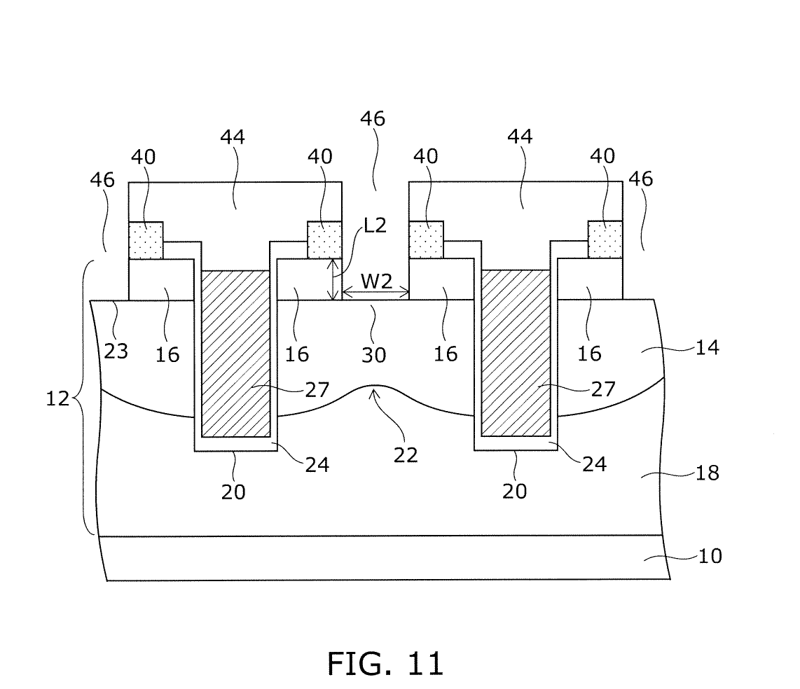

FIGS. 11 to 13 are cross-sectional views showing the process for manufacturing a trench gate MIS transistor according to this embodiment. The manufacturing method up to the step of forming the interlayer insulating film 44 is the same as that of the first embodiment, and hence the description thereof is omitted.

As shown in FIG. 11, the P-type base layer 14 exposed in the second opening 46 is partially removed by dry etching to form a second trench 23. Here, the length L2 of the sidewall and the width W2 of the bottom of the second trench 23 are e.g. about 0.5 micrometers and about 0.4 micrometers, respectively.

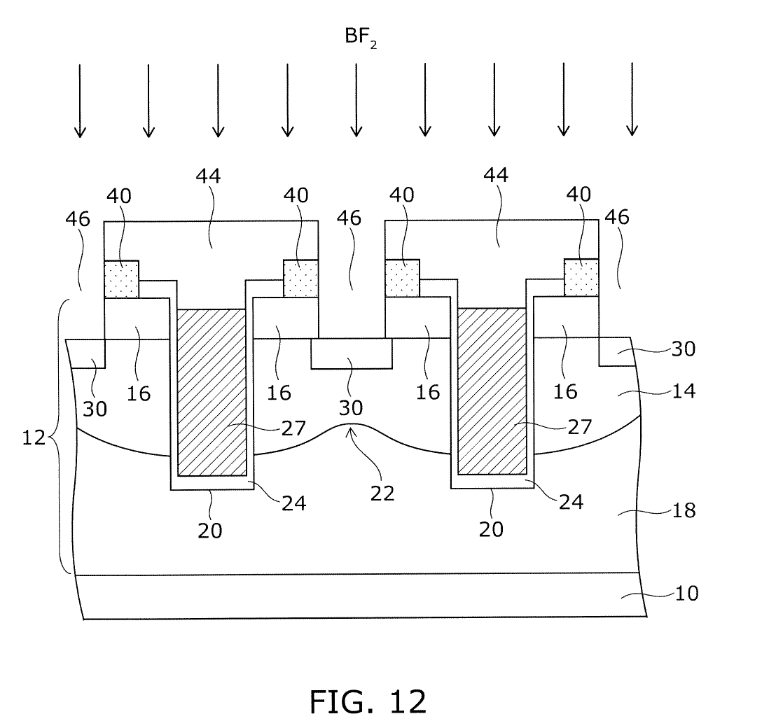

Next, as shown in FIG. 12, ion implantation of BF₂ is performed from above the interlayer insulating film 44 to form a P⁺-type base contact region 30 in the portion of the P-type base layer 14 in contact with the bottom of the second trench 23. Here, the BF₂ ion implantation is illustratively performed under the condition of an ion acceleration energy of 30 keV, a dose amount of 3E15 atmos/cm², and an implantation angle (angle relative to the normal to the semiconductor substrate surface) of 0°. Then the dopants in the P⁺-type base contact region 30 are activated by heat treatment. As a result, the P⁺-type base contact region 30 has a depth of about 0.3 micrometers from the bottom face of the second trench 23 and a dopant concentration of about 1E20 atoms/cm³.

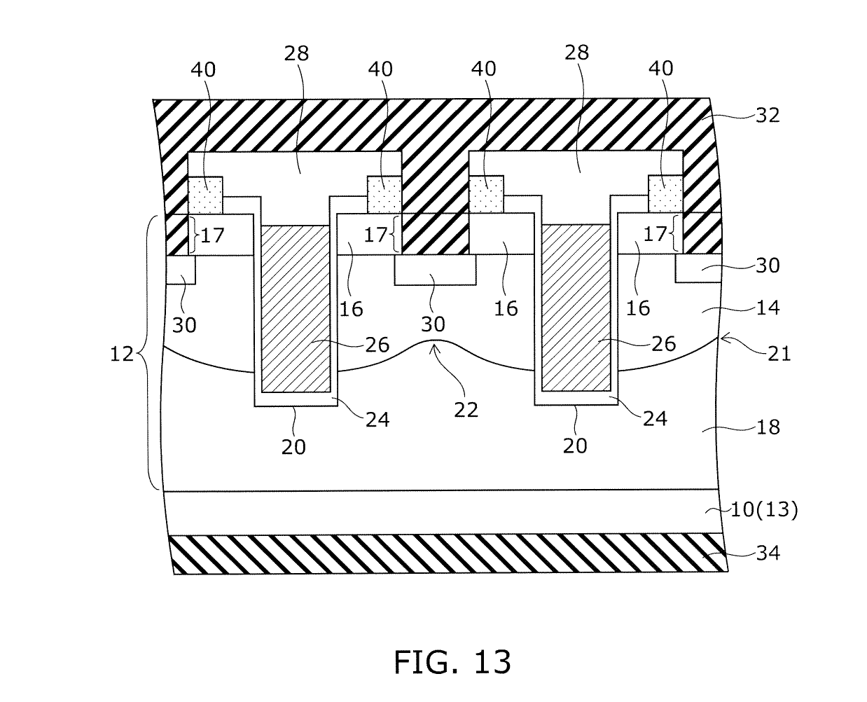

Next, as shown in FIG. 13, a source electrode 32 is provided so as to cover the interlayer insulating film 28 by sputtering under the condition that the P⁺-type base contact region 30 and the sidewall 17 of the N⁺-type source region 16 are exposed. Here, the source electrode 32 is illustratively made of a laminated film composed of TiW or other barrier metal and Al, and is electrically connected to the N⁺-type source region 16 and the P⁺-type base contact region 30. Then a drain electrode 34 is formed on the backside of the N⁺-type semiconductor substrate 10 by sputtering, for example. Thus a trench gate MIS transistor is completed.

### Major Effects of the Second Embodiment

As described above, also in this embodiment, a protruding feature 22 is provided on the bottom face of the P-type base layer 14. As shown in FIG. 10, this protruding feature 22 is designed so that the distance (Lt) from the upper face of the N⁻-type epitaxial layer 12 to the bottom of the P-type base layer 14 adjacent to the sidewall of the first trench is longer than the distance (Lb) from the upper face of the N⁻-type epitaxial layer 12 to the bottom face of the P-type base layer 14 nearly at the center between the first trenches 20. In other words, the protruding feature 22 is designed so that the distance from the upper face of the N⁻-type epitaxial layer 12 to the PN junction interface 21 is minimized nearly at the center between the first trenches 20. It can be also restated that the protruding feature 22 is provided at the position in the PN junction interface 21 corresponding to the P⁺-type base contact region 30. The above-mentioned upper face of the N⁻-type epitaxial layer 12 can be also referred to as the upper face of the P-type base layer 14.

Here, inside the P-type base layer 14 adjacent to the sidewall of the first trench 20, it is necessary to prevent the short channel effect and other unwanted phenomena. To this end, the P-type base layer 14 is provided with a channel length required for such prevention. Furthermore, because the protruding feature 22 is provided on the bottom face of the P-type base layer 14 and the second trench is additionally provided between adjacent first trenches, the distance from inside the P-type base layer 14 to the P⁺-type base contact region 30 can be further reduced. Thus, during the turnoff, the resistance for ejecting carriers from inside the P-type base layer 14 to the source electrode can be further reduced, and the carrier ejection current can be increased. As a result, when the trench gate MIS transistor is turned off, the time period for ejecting carriers from the P-type base layer 14 to the source electrode 32 can be reduced. This reduction of turnoff time enables the total amount of power loss (switching loss) occurring during the turnoff to be reduced.

Also in the manufacturing method of this embodiment, the first insulating film 36 used for forming the first trench 20 is set back by isotropic etching and processed into a second insulating film 40. Then the second insulating film 40 is used as a mask to form the P-type base layer 14, the N⁺-type source region 16, and the trench gate electrode 26 by ion implantation in a self-aligned manner. In conventional methods, the processes for forming the trench, the base layer, and the source region are often performed by photolithography using separate masks. In contrast, in this embodiment, two iterations of photolithography (for the base layer and the source region) can be omitted. As a result, the device manufacturing process can be simplified, and the manufacturing cost can be reduced. Furthermore, the decrease of manufacturing yield due to misalignment of masks can be prevented by reducing the number of masks required for device manufacturing and using the self-alignment technique for forming the P-type base layer, the N⁺-type source region, and the trench gate electrode.

The embodiments of the invention have been described with reference to examples. However, the invention is not limited to these examples.

For example, the invention can be modified for application to various semiconductor devices having the so-called “trench gates” to achieve similar advantageous effects, and such modifications are also encompassed within the scope of the invention. By way of example, the N⁺-type semiconductor substrate in the first and second embodiment described above can be replaced by a P⁺-type semiconductor substrate to provide a trench gate IGBT structure and a method for manufacturing the same. Furthermore, the above embodiments assume that the first conductivity type is illustratively the N-type and that the second conductivity type is illustratively the P-type. However, the embodiments can be practiced also when the N-type and the P-type are interchanged.

In the above embodiments, only silicon is used as an example of semiconductor. However, in addition, semiconductors such as GaAs, SiC, GaN, SiGe, and C may also be used. Furthermore, the above embodiments assume that silicon oxide film is exclusively used for the gate insulating film. However, in addition, a laminated film of silicon nitride film and silicon oxide film (e.g. ONO film), a high-k film, an oxynitride film, or an insulating film made by any combination thereof may also be used.

The material, conductivity type, kind of dopant, dopant concentration, thickness, length, depth, width, and positional relationship of each element of the semiconductor device described above that are variously adapted by those skilled in the art are also encompassed within the scope of the invention as long as they include the features of the invention.

The above configurations of the semiconductor device and the method for manufacturing the same may include any known elements appropriately selected by those skilled in the art, and such configurations are also encompassed within the scope of the invention as long as they include the features of the invention.

1. A semiconductor device comprising:
a first semiconductor layer of a first conductivity type;
a second semiconductor layer of a second conductivity type provided on the first semiconductor layer;
a plurality of first trenches passing through the second semiconductor layer and reaching the first semiconductor layer;
a gate insulating film provided on an inner wall of the first trench; and
a gate electrode filling in the first trench via the gate insulating film,
a PN junction interface being provided between the first semiconductor layer and the second semiconductor layer, and
a distance from an upper face of the second semiconductor layer to the PN junction interface being minimized nearly at a center between the first trenches.

2. The semiconductor device according to claim 1, further comprising:
a second trench provided between the adjacent first trenches; and
a contact region of the second conductivity type provided at a bottom of the second trench and electrically connected to the second semiconductor layer.

3. The semiconductor device according to claim 1, wherein the first semiconductor layer and the second semiconductor layer include at least one selected from the group consisting of Si, GaAs, SiC, GaN, SiGe, and C.

4. The semiconductor device according to claim 1, wherein the gate insulating film includes at least one selected from the group consisting of a silicon oxide film, a laminated film of silicon nitride film and silicon oxide film, a film having a dielectric constant higher than silicon oxide, an oxynitride film, and an insulating film made by any combination thereof.

5. The semiconductor device according to claim 1, further comprising:
a third semiconductor layer of the second conductivity type provided on a surface of the first semiconductor layer, the surface being opposite to a surface on which the second semiconductor layer is provided.

6. A semiconductor device comprising:
a first semiconductor layer of a first conductivity type;
a second semiconductor layer of a second conductivity type provided on the first semiconductor layer;
a plurality of first trenches passing through the second semiconductor layer and reaching the first semiconductor layer;
a gate insulating film provided on an inner wall of the first trench;
a gate electrode filling in the first trench via the gate insulating film;
a plurality of first diffusion regions of the first conductivity type selectively provided in the upper surface of the second semiconductor layer; and
a contact region of the second conductivity type provided between the first diffusion regions in the second semiconductor layer,
a PN junction interface being provided between the first semiconductor layer and the second semiconductor layer, and
the PN junction interface having a protruding feature at a position corresponding to the contact region.

7. The semiconductor device according to claim 6, wherein the first semiconductor layer and the second semiconductor layer include at least one selected from the group consisting of Si, GaAs, SiC, GaN, SiGe, and C.

8. The semiconductor device according to claim 6, wherein the gate insulating film includes at least one selected from the group consisting of a silicon oxide film, a laminated film of silicon nitride film and silicon oxide film, a film having a dielectric constant higher than silicon oxide, an oxynitride film, and an insulating film made by any combination thereof.

9. The semiconductor device according to claim 6, further comprising:
a third semiconductor layer of the second conductivity type provided on a surface of the first semiconductor layer, the surface being opposite to a surface on which the second semiconductor layer is provided.

10. A method for manufacturing a semiconductor device comprising:
forming a first insulating film on an upper face of a first semiconductor crystal layer of a first conductivity type;
forming a plurality of first openings in the first insulating film and then partially removing the first semiconductor crystal layer exposed in the first openings to form a plurality of first trenches;
setting back the first insulating film having the first openings to form a second insulating film and to expose an upper corner of the first trench;
forming a gate insulating film on an inner wall of the first trench;
filling in the first trench with a gate electrode material via the gate insulating film;
introducing a first dopant of a second conductivity type and a second dopant of the first conductivity type into the corner and the gate electrode material, respectively, by ion implantation from above the first semiconductor crystal layer using the second insulating film as a mask; and
thermally diffusing the first dopant and the second dopant introduced into the corner and the gate electrode material to convert the gate electrode material into a conductor of the first conductivity type, to form a second semiconductor layer of the second conductivity type in the first semiconductor crystal layer, and to form a diffusion region of the first conductivity type in the corner.

11. The method for manufacturing a semiconductor device according to claim 10, further comprising:
forming an interlayer insulating film so as to overlie the first trench, the corner, and the second insulating film;
forming a second opening in a portion of the interlayer insulating film, the portion corresponding to above a position between the adjacent first trenches, and then partially removing the first semiconductor crystal layer exposed in the second opening to form a second trench; and
forming a contact region of the second conductivity type electrically connected to the second semiconductor layer by ion implantation of the second conductivity type using the interlayer insulating film having the second opening as a mask.

12. The method for manufacturing a semiconductor device according to claim 10, wherein the first semiconductor layer and the second semiconductor layer include at least one selected from the group consisting of Si, GaAs, SiC, GaN, SiGe, and C.

13. The method for manufacturing a semiconductor device according to claim 10, wherein the gate insulating film includes at least one selected from the group consisting of a silicon oxide film, a laminated film of silicon nitride film and silicon oxide film, a film having a dielectric constant higher than silicon oxide, an oxynitride film, and an insulating film made by any combination thereof.

14. The method for manufacturing a semiconductor device according to claim 10, wherein the first semiconductor crystal layer includes Si, and the first and second dopant are boron and arsenic, respectively.

15. The method for manufacturing a semiconductor device according to claim 10, wherein the step of setting back the first insulating film uses isotropic etching.
